(19) United States
(12) Patent Application Publication
(10) Pub. No.: US 2002/0175721 A1
(43) Pub. Date: Nov. 28, 2002

(54) Frame synchronism detection circuit

(76) Inventors: Yoshinori Kanda, Tokyo (JP); Toshiyuki Tanabe, Kanagawa (JP)

Correspondence Address: McGinn& Gibb, PLLC, Suite 200, 8321 Old Courthouse Road, Vienna, VA, 22182-3817, US

(21) Appl. No.: 10/152,623

(22) Filed: May 23, 2002

(30) Foreign Application Priority Data
May 28, 2001 (JP) 2001-159340

(51) Int. Cl. H03L 7/00

(52) U.S. Cl. 327/141

(57) ABSTRACT

A frame synchronism detection circuit is disclosed which does not consume much power even when a hunting state continues for a long period of time. A master synchronization circuit receives a main signal and an operation clock to detect a synchronization pattern first and outputs a synchronization state signal when synchronism is established. Gate circuits operate in response to the synchronization state signal outputted from the master synchronization circuit to supply operation clocks to slave synchronization circuits. The slave synchronization circuits normally receive supply of main signals and receive the operation clocks through the gate circuits to start operation thereof to establish synchronism.

### BACKGROUND OF THE INVENTION

1. Field of the Invention

The present invention relates to a frame synchronism detection circuit, and more particularly to a frame synchronism detection circuit which establishes synchronism of a plurality of main signals of a low bit rate obtained by frame conversion of a main signal which has a synchronization pattern in a frame thereof.

2. Description of the Related Art

A synchronous digital hierarchy (SDH) technique based on a synchronous optical network (SONET) technique which uses an optical fiber has been standardized by the International Telecommunication Union-Telecommunication Standardization Sector (ITU-T).

A signal communicated by a transmission system which employs the SDH technique has a synchronization pattern at a particular position in a frame.

Generally, transmission of a signal between stations is carried out at a high bit rate using an optical fiber. However, in each station, in order to make it possible to execute signal processing with a high degree of reliability, the signal is frame-converted into a plurality of main signals of a lower bit rate. A synchronization circuit is provided for each of the plurality of main signals obtained by such frame conversion and recognizes the synchronization pattern in a frame to establish frame synchronism of the main signals.

FIG. 12 shows an example of a configuration of a conventional frame synchronism detection circuit.

Referring to FIG. 12, the frame synchronism detection circuit shown includes a frame conversion circuit 10 which converts a main signal D10 inputted thereto into main signals D11, D12, D13 and D14 of a lower bit rate and produces operation clock signals CL11, CL12, CL13 and CL14 synchronized with the main signal D10. The main signals D11 to D14 and the operation clock signals CL11 to CL14 are outputted to synchronization circuits 11, 12, 13 and 14, respectively.

FIG. 13 illustrates an example of a configuration of the main signal D10 and the main signals D11 to D14 obtained by the frame conversion described above.

Referring to FIG. 13, the main signal D10 inputted is a signal in which data of a plurality of channels, four channels in FIG. 13, are time-division multiplexed, and has a synchronization pattern PT inserted at a particular position in each frame thereof. Meanwhile, each of the main signals D11 to D14 obtained by the frame conversion is a main signal having the synchronization pattern PT in each frame thereof, and the phase differences among the synchronization patterns in the main signals are very small.

The synchronization circuits 11 to 14 receive the main signals D11 to D14 and the operation clock signals CL11 to CL14, respectively, and detect the synchronization pattern to individually establish synchronism.

However, where a plurality of synchronism circuits individually detect a synchronization pattern to establish synchronism as in the conventional frame synchronism detection circuit described above, the entire circuit exhibits high power consumption when the synchronism circuits are in a hunting state wherein they cannot detect and therefore are searching for the synchronization pattern.

Particularly in such a case that a fault such as a circuit disconnection occurs or a fault occurs with a plurality of channels, the hunting state continues for a long time. Therefore, the conventional frame synchronism detection circuit is disadvantageous in that not only it suffers from high power consumption but also the reliability is deteriorated by heat generation of a circuit in an LSI.

### SUMMARY OF THE INVENTION

It is an object of the present invention to provide a frame synchronism detection circuit which does not consume much power even when a fault such as disconnection of a circuit occurs or a fault occurs with a plurality of channels and consequently a hunting state continues for a long period of time and can therefore solve the problem of heat generation of an LSI.

In order to attain the object described above, according to the present invention, there is provided a frame synchronism detection circuit, comprising a master synchronization circuit and a plurality of slave synchronization circuits for receiving individual main signals having frames including a synchronization pattern at substantially same timings and operation clocks for the main signals to establish synchronism, and synchronization circuit controlling means for controlling the slave synchronization circuits to start operation to establish synchronism after the master synchronization circuit enters a synchronization state or a pre-synchronization state.

Preferably, the synchronization circuit controlling means controls the main signals or/and the operation clocks to be supplied to the slave synchronization circuits to cause the slave synchronization circuits to start the operation.

Preferably, the master synchronization circuit determines transition from a hunting state to the pre-synchronization state when the synchronization pattern is detected once, and then determines transition to the synchronization state when the synchronization pattern is detected successively by n times, n being an integer equal to or greater than 2.

Further preferably, each of the slave synchronization circuits determines transition from the hunting state to the pre-synchronization state when the synchronization pattern is detected once after the operation thereof is started, and then determines transition to the synchronization state when the synchronization pattern is detected successively by n times or by n−1 times.

The synchronization circuit controlling means may delay starting of the operation of the slave synchronization circuits within a period of time until a next synchronization pattern is inputted to the master synchronization circuit after the master synchronization circuit enters the synchronization state or the pre-synchronization state.

Preferably, the synchronization circuit controlling means supplies only those portions of the main signals in the proximity of the synchronization pattern to the slave synchronization circuits.

The synchronization circuit controlling means may include a switch circuit for selecting validity/invalidity of the signals to be outputted to the slave synchronization circuits.

According to a preferred form, the master synchronization circuit receives one of the main signals and one of the operation clocks to detect the synchronization pattern and outputs a synchronization state signal when the master synchronization circuit establishes synchronism, the synchronization circuit controlling means including gate circuits for individually receiving the other operation clocks than the operation clock supplied to the master synchronization circuit and controlling supply of the received operation clocks to the slave synchronization circuits in response to the synchronization state signal, the slave synchronization circuits starting the operation based on the other main signals than the main signal supplied to the master synchronization circuit and the operation clocks individually supplied thereto through the gate circuits.

According to another preferred form, the master synchronization circuit receives one of the main signals and one of the operation clocks to detect the synchronization pattern and outputs a synchronization state signal when the master synchronization circuit establishes synchronism, the synchronization circuit controlling means including gate circuits for individually receiving the other main signals than the main signal supplied to the master synchronization circuit and controlling supply of the received main signals to the slave synchronization circuits in response to the synchronization state signal, the slave synchronization circuits starting the operation based on the other operation clocks than the operation clock supplied to the master synchronization circuit and the main signals individually supplied thereto through the gate circuits.

According to a further preferred form, the master synchronization circuit receives one of the main signals and one of the operation clocks to detect the synchronization pattern and outputs a synchronization state signal when the master synchronization circuit establishes synchronism, the synchronization circuit controlling means including first gate circuits for individually receiving the other operation clocks than the operation clock supplied to the master synchronization circuit and controlling supply of the received operation clocks to the slave synchronization circuits in response to the synchronization state signal and second gate circuits for individually receiving the other main signals than the main signal supplied to the master synchronization circuit and controlling supply of the received main signals to the slave synchronization circuits in response to the synchronization state signal, the slave synchronization circuits starting the operation based on the operation clocks and the main signals individually supplied thereto through the first gate circuits and the second gate circuits, respectively.

According to a still further preferred form, the master synchronization circuit receives one of the main signals and one of the operation clocks to detect the synchronization pattern and outputs a timing position signal representative of the proximity of the synchronization pattern after the master synchronization circuit establishes synchronism, the synchronization circuit controlling means including gate circuits for individually receiving the other main signals than the main signal supplied to the master synchronization circuit and controlling supply of the received main signals to the slave synchronization circuits in response to the timing position signal, the slave synchronization circuits starting the operation based on the other operation clocks than the operation clock supplied to the master synchronization circuit and the main signals only in the proximity of the synchronization pattern individually supplied thereto through the gate circuits.

With the frame synchronism detection circuit, one of a plurality of synchronization circuits, that is, a master synchronization circuit, is rendered operative first, and then after the master synchronization circuit enters a synchronization state or a pre-synchronization state, main signals or/and operation clocks are supplied to the other synchronization circuits, that is, to the slave synchronization circuits to start their operation. Consequently, even if disconnection of a circuit or a fault in a plurality of channels occurs, the power consumption of the entire circuit can be reduced.

Where starting of the operation of the slave synchronization circuits is delayed within a period of time until a next synchronization pattern is inputted to the master synchronization circuit, further reduction in power consumption can be achieved.

Further, where only those portions of the main signals in the proximity of the synchronization pattern are supplied to the slave synchronization circuits to render the latter operative, reduction of the power consumption and prevention of erroneous synchronization can be achieved.

Where the master synchronization circuit determines transition from a hunting state to the pre-synchronization state when the synchronization pattern is detected once and then determines, after the transition to the pre-synchronization state, transition to the synchronization state when the synchronization pattern is detected successively by n times, n being an integer equal to or greater than 2, if each of the slave synchronization circuits determines transition from the hunting state to the pre-synchronization state when the synchronization pattern is detected once after the operation thereof is started and then determines, after the transition to the pre-synchronization state, transition to the synchronization state when the synchronization pattern is detected successively by n−1 times, then the synchronism can be established at the same frame between the master synchronization circuit and the slave synchronization circuits.

Furthermore, where the synchronization circuit controlling means includes a switch circuit for selecting validity/invalidity of the signal outputted from the master synchronization circuit in order to control the main signals or/and the operation clocks to be supplied to the slave synchronization circuits, the slave synchronization circuits can operate independently of the master synchronization circuit.

The above and other objects, features and advantages of the present invention will become apparent from the following description and the appended claims, taken in conjunction with the accompanying drawings in which like parts or elements are denoted by like reference symbols.

### BRIEF DESCRIPTION OF THE DRAWINGS

FIG. 1 is a block diagram showing a frame synchronism detection circuit to which the present invention is applied;

FIG. 2 is a timing chart illustrating operation of the frame synchronism detection circuit of FIG. 1;

FIG. 3 is a block diagram showing another frame synchronism detection circuit to which the present invention is applied;

FIG. 4 is a timing chart illustrating operation of the frame synchronism detection circuit of FIG. 3;

FIG. 5 is a block diagram showing a further frame synchronism detection circuit to which the present invention is applied;

FIG. 6 is a block diagram showing a modification to the frame synchronism detection circuit of FIG. 3;

FIG. 7 is a timing chart illustrating operation of the frame synchronism detection circuit of FIG. 6;

FIGS. 8 and 9 are timing charts illustrating different operations of the frame synchronism detection circuit of FIG. 1;

FIG. 10 is a block diagram showing a modification to the frame synchronism detection circuit of FIG. 1;

FIG. 11 is a diagrammatic view illustrating state transition until a synchronization circuit establishes synchronism;

FIG. 12 is a block diagram showing a conventional frame synchronism detection circuit; and

FIG. 13 is a waveform diagram illustrating an example of a conventional configuration of main signals.

### DESCRIPTION OF THE PREFERRED EMBODIMENTS

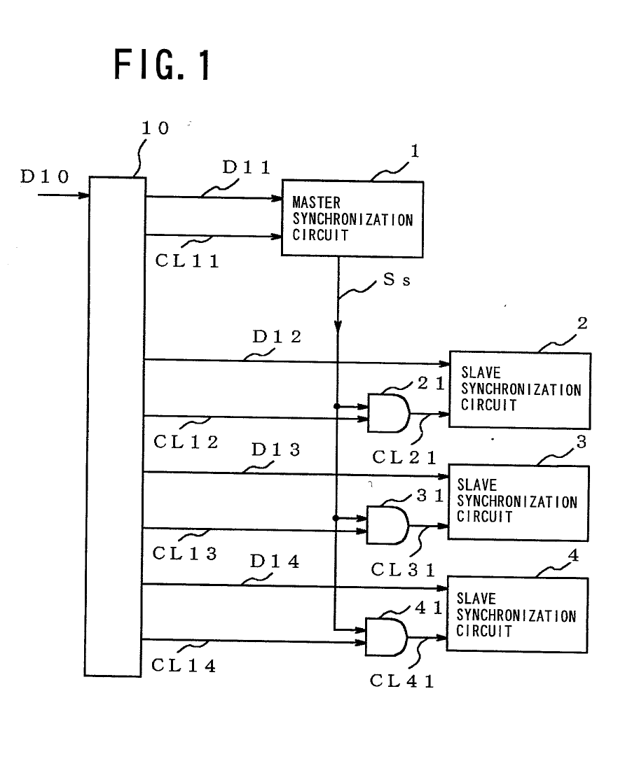

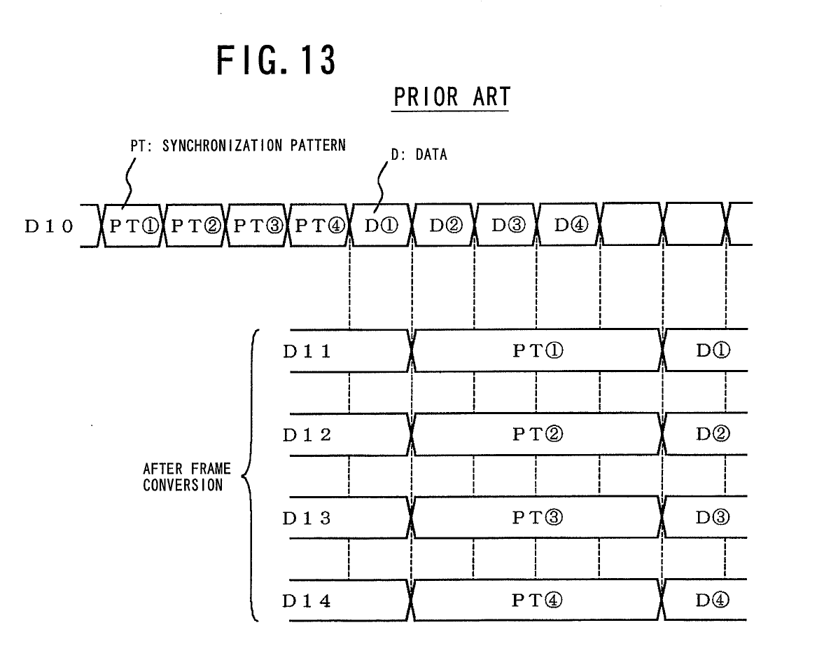

Referring to FIG. 1, there is shown a frame synchronism detection circuit to which the present invention is applied. The frame synchronism detection circuit shown includes a frame conversion circuit 10 which receives a main signal D10 as an input signal and outputs main signals D11, D12, D13 and D14 and operation clocks CL11, CL12, CL13 and CL14. The signals D10 and D11 to D14 and CL11 to CL14 are similar to those described hereinabove with reference to FIG. 13.

The frame synchronism detection circuit further includes a master synchronization circuit 1 which receives the main signal D11 and the operation clock CL11 to detect a synchronization pattern and outputs a synchronization state signal Ss when the synchronism is established, gate circuits 21, 31 and 41 which control the operation clocks CL12 to CL14 in response to the synchronization state signal Ss outputted from the master synchronization circuit 1 and output them as operation clocks CL21, CL31 and CL41, respectively, and slave synchronization circuits 2 to 4 which receive the main signals D12 to D14 and the operation clocks CL21, CL31 and CL41, respectively, to start operation thereof.

The frame synchronization detection circuit is configured such that, in order to suppress the electric power consumption through continuation of a hunting state in a plurality of synchronization circuits, the master synchronization circuit 1 establishes the synchronism first, and then, the operation of the slave synchronization circuits 2 to 4 is started after the synchronism is established by the master synchronization circuit 1.

The slave synchronization circuits 2 to 4 normally receive the supply of the main signals D12 to D14, respectively, and start operation thereof when they receive the operation clocks CL21, CL31 and CL41 through gate circuits 21, 31 and 41, respectively.

Itistobenotedthat, since the electric power consumption by transient current upon switching is dominant in a circuit formed from the CMOS, the electric power consumption of the =slave synchronization circuits 2 to 4 which is formed from the CMOS is substantially 0 until the operation clock is supplied thereto.

Further, since timing differences of the synchronization pattern among the main signals D11 to D14 are very small, if operation of the slave synchronization circuits 2 to 4 is started in accordance with a timing at which the synchronism of the master synchronization circuit 1 is established, a next synchronization pattern can be detected in a short time to establish the synchronism.

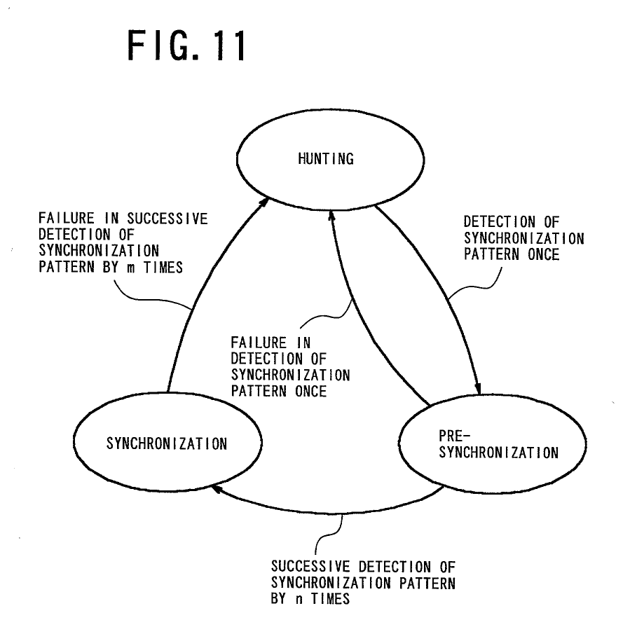

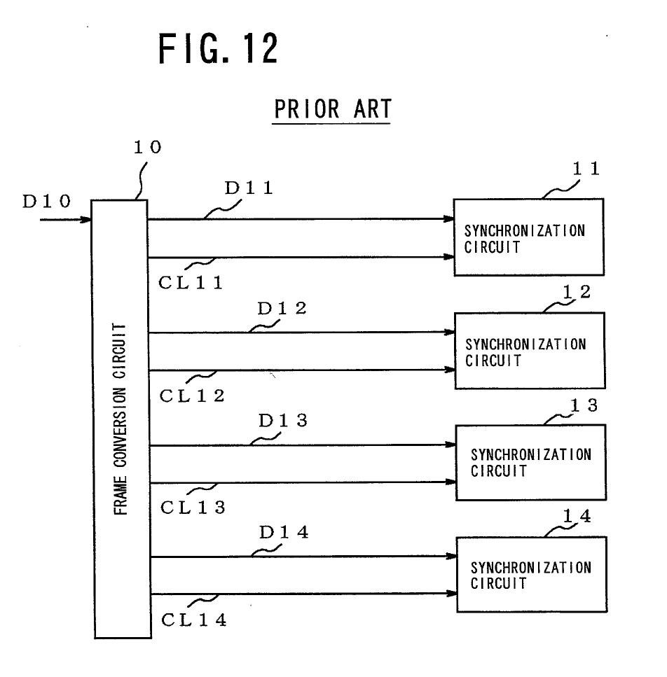

Generally, the state transition until a synchronization circuit detects a synchronization pattern to establish the synchronism occurs, as shown in FIG. 11, in order like the hunting state —pre-synchronization state —synchronization state.

If the synchronization pattern is detected once in the hunting state, then the state transfers to the pre-synchronization state, and if the synchronization pattern is detected successively by a plural number of times (n times) in the pre-synchronization state, then the state transfers to the synchronization state. Further, if the synchronization pattern cannot be detected at all after the state transfers to the pre-synchronization state, then the state returns to the hunting state. Furthermore, if the synchronization pattern cannot be detected successively by another predetermined number of times (m times) after the state transfers to the synchronization state, then the state returns to the hunting state.

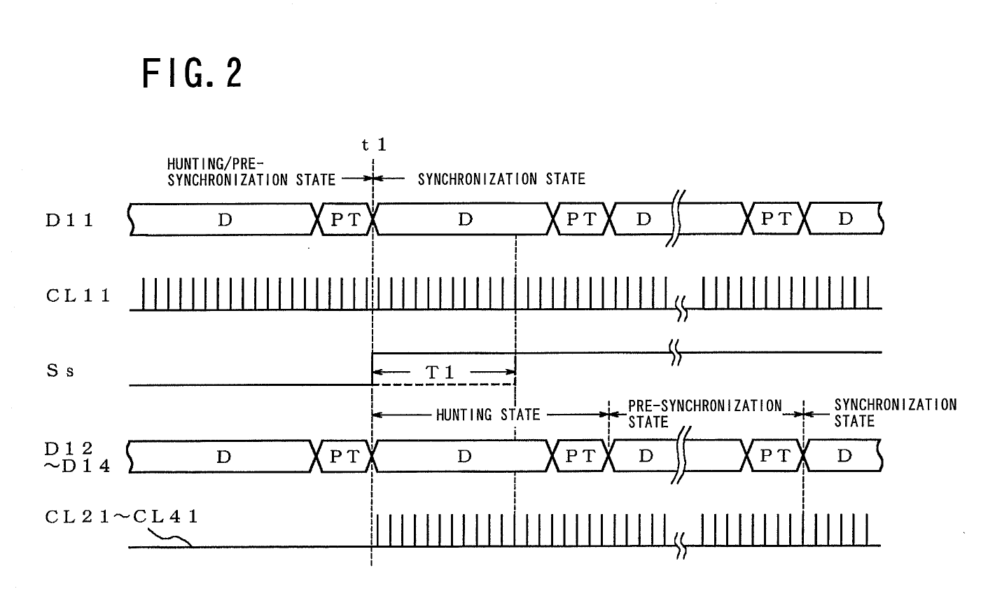

Operation of the frame synchronism detection circuit of FIG. 1 is described below with reference to a timing chart shown in FIG. 2.

The master synchronization circuit 1 detects, at time t1, a synchronization pattern (PT) of the main signal D11 and changes the state from a hunting/pre-synchronization state to the synchronization state. At this time, the master synchronization circuit 1 sets the synchronization state signal Ss to be supplied to the gate circuits 21, 31 and 41 to the ‘H’ (high) level.

The gate circuits 21, 31 and 41 receive the ‘H’ level synchronization state signal Ss and change the state into an on state to allow the operation clocks CL21, CL31 and CL41 to be supplied to the slave synchronization circuits 2 to 4, respectively.

The slave synchronization circuits 2 to 4 normally receive the supply of the main signals D12 to D14, and start their operation when they receive the operation clocks CL21, CL31 and CL41, respectively. Then, they detect the,synchronization pattern (PT) of the main signals D12 to D14 and change their state into the synchronization state through the hunting state and the pre-synchronization state.

In the configuration described above, the slave synchronization circuits 2 to 4 are inoperative when the master synchronization circuit 1 is in the hunting pre-synchronization state, and as a result, power consumption of them is approximately 0. Consequently, even if circuit disconnection or a fault in a plurality of channels occurs and the hunting state continues, the power consumption of the overall circuit can be reduced.

Incidentally, the slave synchronization circuits 2 to 4 start their operation at time t1 to detect a next synchronization pattern. However, there is no trouble even if the operation of them remains stopping until a next synchronization pattern is inputted to them.

Therefore, if, taking an operation starting buildup time of the slave synchronization circuits into consideration, a suitable time T1 till a point of time at which a next synchronization pattern is inputted is set and the synchronization state signal Ss is outputted after it is delayed by the time T1, then the operation period of the slave synchronization circuits is reduced by the time T1. Consequently, the power consumption can be reduced still further.

While four synchronization circuits are used in the configuration described above, if a greater number of synchronization circuits are used, then a higher effect of power consumption reduction can be achieved. For example, where sixteen synchronization circuits are used, they involve one master synchronization circuit and fifteen slave synchronization circuits. In this case, the power consumption when the master synchronization circuit is in the hunting/pre-synchronization state can be reduced to 1/16 when compared with al alternative case wherein all sixteen synchronization circuits always operate as in a conventional example.

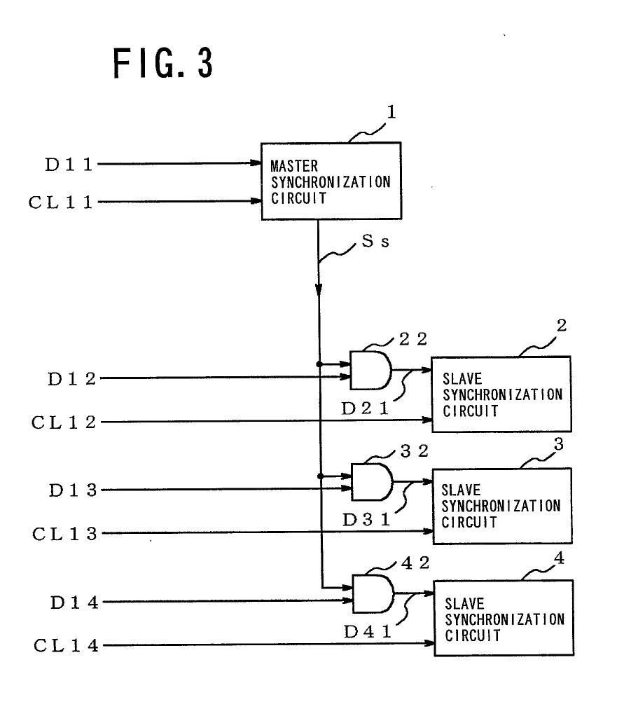

FIG. 3 shows another frame synchronism detection circuit to which the present invention is applied.

Referring to FIG. 3, the frame synchronism detection circuit shown includes a frame conversion circuit (not shown), a master synchronization circuit 1 and slave synchronization circuits 2, 3 and 4 similar to those shown in FIG. 1 and further includes gate circuits 22, 32 and 42 without including the gate circuits 21, 31 and 41 shown in FIG. 1, respectively. In the present frame synchronism detection circuit, the main signals D12 to D14 to be supplied to the slave synchronization circuits 2 to 4 are controlled in accordance with the synchronism state signal Ss, different from the frame synchronism detection circuit of FIG. 1.

More particularly, the master synchronization circuit 1 receives a main signal D11 and an operation clock CL11 from the frame conversion circuit to detect a synchronization pattern and outputs a synchronism state signal Ss when the synchronism is established. The gate circuits 22, 32 and 42 control main signals D12 to D14 from the frame conversion circuit in accordance with the synchronism state signal Ss from the master synchronization circuit 1 and output the controlled main signals as main signals D21, D31 and D41, respectively. The slave synchronization circuits 2, 3 and 4 receive operation clocks CL12 to CL14 from the frame conversion circuit and the main signals D21, D31 and D41 from the gate circuits 22, 32 and 42, respectively, to start operation thereof.

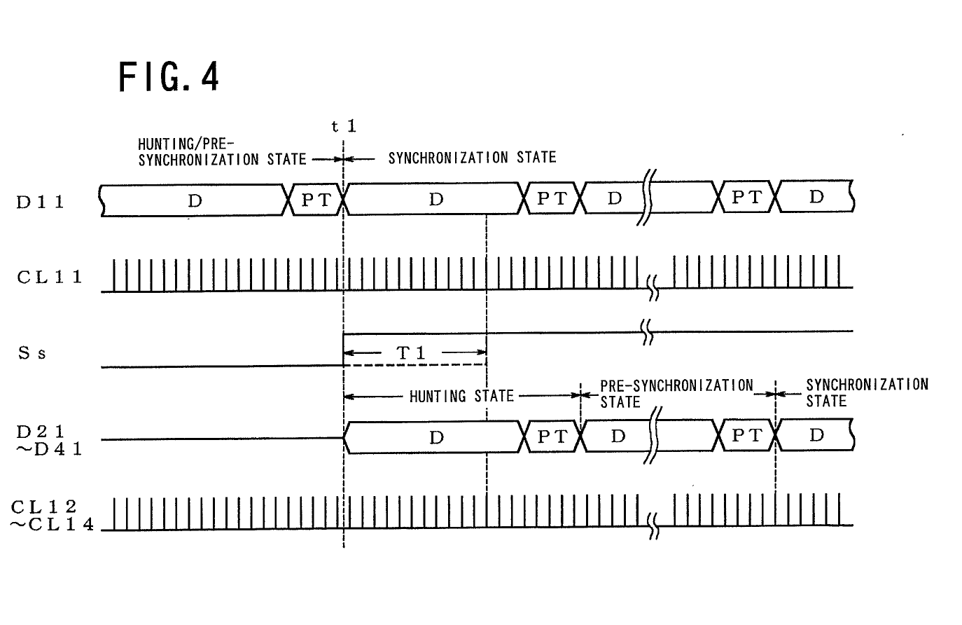

Operation of the frame synchronism detection circuit of FIG. 3 is described below with reference to FIG. 4.

The master synchronization circuit 1 detects, at time t1, a synchronization pattern (PT) of the main signal D11 and changes the state from a hunting/pre-synchronization state to a synchronization state. At this time, the master synchronization circuit 1 sets the synchronization state signal Ss to be supplied to the gate circuits 22, 32 and 42 to the ‘H’ level.

The gate circuits 22, 32 and 42 receive the ‘H’ level synchronization state signal Ss and change the state thereof into an on state thereby to allow the main signals D21, D31 and D41 to be supplied to the slave synchronization circuits 2 to 4, respectively.

The slave synchronization circuits 2 to 4 normally receive the supply of the operation clocks CL12 to CL14 and start their operation when they receive the main signals D21, D31 and D41, respectively. Then, they detect the synchronization pattern (PT) of the main signals D21, D31 and D41, respectively, and change the state into the synchronization state through the hunting state and the pre-synchronization state.

It is to be noted that, if, taking an operation starting build up time of the slave synchronization circuits into consideration, a suitable time period T1 until a next synchronization pattern is inputted is set and the synchronization state signal Ss is outputted after a delay by the time period T1, then the operation period of the slave synchronization circuits is reduced by the time T1. Consequently, the power consumption can be reduced still further.

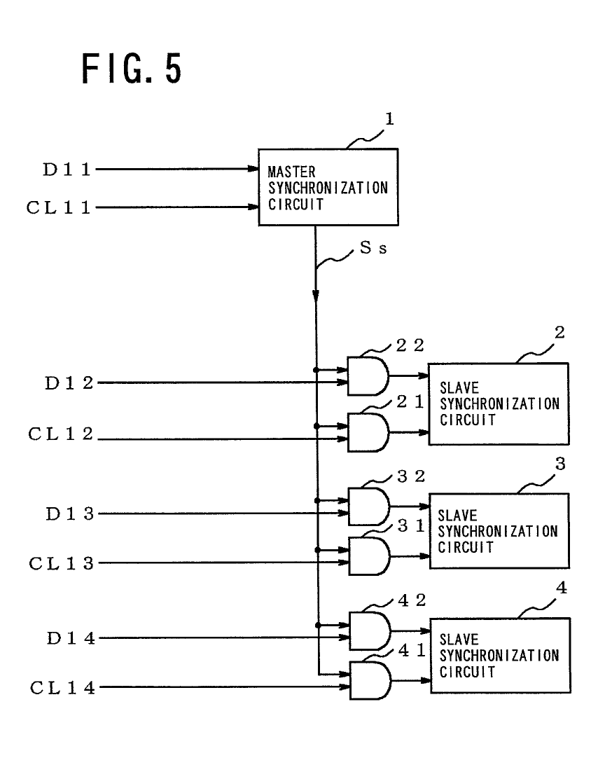

FIG. 5 shows a further frame synchronism detection circuit to which the present invention is applied.

Referring to FIG. 5, the frame synchronism detection circuit shown includes a frame conversion circuit (not shown), a master synchronization circuit 1, slave synchronization circuits 2, 3 and 4 and gate circuits 21, 31 and 41 similar to those shown in FIG. 1 and further includes gate circuits 22, 32 and 42 similar to those shown in FIG. 3. In other words, the present frame synchronism detection circuit is a combination of the frame synchronism detection circuits of FIGS. 1 and 3. Thus, in the present frame synchronism detection circuit, the main signals D12 to D14 and the operation clocks CL12 to CL14 to be supplied to the slave synchronization circuits 2 to 4 are controlled in accordance with the synchronism state signal Ss, different from the frame synchronism detection circuits of FIGS. 1 and 3.

More particularly, the gate circuits 21, 31 and 41 control operation clocks CL12 to CL14 in accordance with the synchronization state signal Ss and output the controlled operation clocks to the slave synchronization circuit 2 to 4, respectively. Meanwhile, the gate circuits 22, 32 and 42 control main signals D12 to D14 in accordance with the synchronization state signal Ss and output the controlled main signals to the slave synchronization circuits 2 to 4. The gate circuits 21, 31 and 41 are turned to an on state in accordance with the synchronization state signal Ss from the master synchronization circuit 1 and output the operation clocks and the main signals supplied thereto to the slave synchronization circuits 2 to 4 to start operation of the slave synchronization circuits 2 to 4, respectively.

In the frame synchronism detection circuit, when the master synchronization circuit 1 is in the hunting/pre-synchronization state, the main signals and the operation clocks are not supplied to the slave synchronization circuits 2 to 4, and consequently, the slave synchronization circuits 2 to 4 do not operate. Consequently, power consumption can be reduced.

Further, if, taking an operation starting build up time of the slave synchronization circuits into consideration, a suitable time period T1 until a next synchronization pattern is inputted is set and the synchronization state signal Ss is outputted after a delay by the time period T1, then the operation period of the slave synchronization circuits is limited. Consequently, the power consumption can be reduced still further.

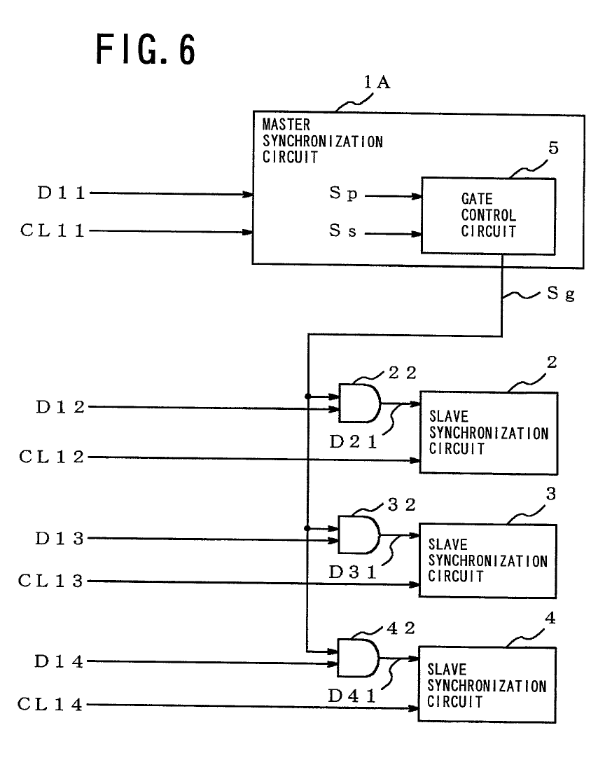

FIG. 6 shows a modification to the frame synchronism detection circuit described hereinabove with reference to FIG. 3. The modified frame synchronism detection circuit is different from the frame synchronism detection circuit of FIG. 3 in that only portions of the main signals D12 to D14 in the proximity of the synchronization pattern are supplied from a master synchronization circuit 1A to the slave synchronization circuits 2 to 4, respectively.

Since a synchronization circuit detects a synchronization pattern of a main signal to establish the synchronism, the operation period of the synchronization circuit can be limited to a portion of the main signal in the proximity of the synchronization pattern. Where slave synchronization circuits operate in the proximity of the synchronization pattern, erroneous synchronism which occurs when data having the same array with the synchronization pattern is included within an interval other than the synchronization pattern (in the SDH, within a payload part) can be prevented.

In the modified frame synchronism detection circuit, after the synchronism of the master synchronization circuit 1A is established, main signals are supplied to the slave synchronization circuits 2, 3 and 4 to start their operation so that their power consumption may be suppressed, and only those portions of the main signals in the proximity of the synchronization pattern are supplied to prevent erroneous synchronism.

To this end, the master synchronization circuit 1A includes a gate control circuit 5which generates a gate control signal Sg to be used to control the gate circuits 22, 32 and 42.

The gate control circuit 5produces the gate control signal Sg based on a synchronization state signal Ss outputted from the inside of the master synchronization circuit 1A and a synchronization pattern timing position signal Sp outputted from the inside of the master synchronization circuit 1A and representative of a timing position of the synchronization pattern.

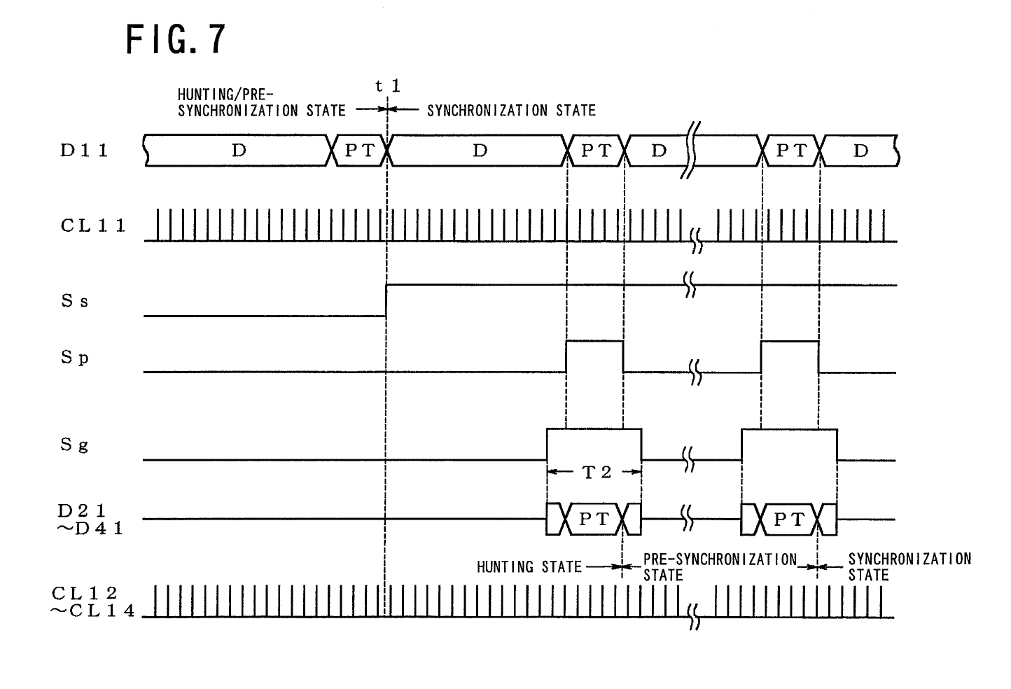

Now, operation of the modified frame synchronism detection circuit of FIG. 6 is described with reference to FIG. 7.

The master synchronization circuit 1A receives the main signal D11 and the operation clock CL11 from the frame conversion circuit not shown to detect the synchronization pattern (PT) of the main signal D11 and changes its state from the hunting/pre-synchronization state to the synchronization state at time t1. At this time, the master synchronization circuit 1A sets the synchronization state signal Ss to the ‘H’ level and outputs it to the gate control circuit 5, and further outputs a synchronization pattern timing position signal Sp.

The gate control circuit 5 generates a gate control signal Sg based on the synchronization state signal Ss and the synchronization pattern timing position signal Sp and outputs the gate control signal Sg to the gate circuits 22, 32 and 42. The gate control signal Sg is used to control the supply of the main signals D12, D13 and D14 and exhibits the ‘H’ level for a predetermined time period T2 which includes the synchronization pattern (PT).

The predetermined time period T2 is set adding a margin before and after the synchronization pattern (PT) of the main signal D11 taking phase differences among the main signals D12, D13 and D14 and operating starting build up times of the slave synchronization circuits 2, 3 and 4 into consideration.

Since the gate circuits 22, 32 and 42 operate in response to the gate control signal Sg, only those portions of the main signals D12, D13 and D14 in the proximity of the synchronization pattern are supplied as main signals D21, D31 and D41 to the slave synchronization circuits 2, 3 and 4, respectively.

The slave synchronization circuits 2, 3 and 4 normally receive the supply of the operation clocks CL12, CL13 and CL14 and receive the main signals D21, D31 and D41 representative only of those portions of the main signals D12, D13 and D14 in the proximity of the synchronization pattern to detect the synchronization pattern (PT), and enters the synchronization state through the hunting state and the pre-synchronization pattern.

Since only those portions of the main signals D12, D13 and D14 in the proximity of the synchronization pattern are supplied to the slave synchronization circuits 2, 3 and 4 in this manner, respectively, the power consumption can be reduced and erroneous synchronization can be prevented.

In the frame synchronism detection circuits described above with reference to FIGS. 1, 3, 5 and 6, the slave synchronization circuits 2, 3 and 4 start their operation after the synchronism of the master synchronization circuit 1 or 1A is established. However, it is otherwise possible for the slave synchronization circuits 2, 3 and 4 to start their operation after the master synchronization circuit 1 changes from the hunting state to the pre-synchronization state.

Referring to FIG. 11, a synchronization circuit changes to the pre-synchronization state when the synchronization pattern is detected once while it is in the hunting state, and then changes to the synchronization state when the synchronization pattern is detected successively by a predetermined number of times while it is in the pre-synchronization state.

Thus, it is determined that the master synchronization circuit and the slave synchronization circuits change to the synchronization state when the synchronization pattern (PT) is detected successively by n times (n is an integer equal to or greater than 2) after they change to the pre-synchronization state.

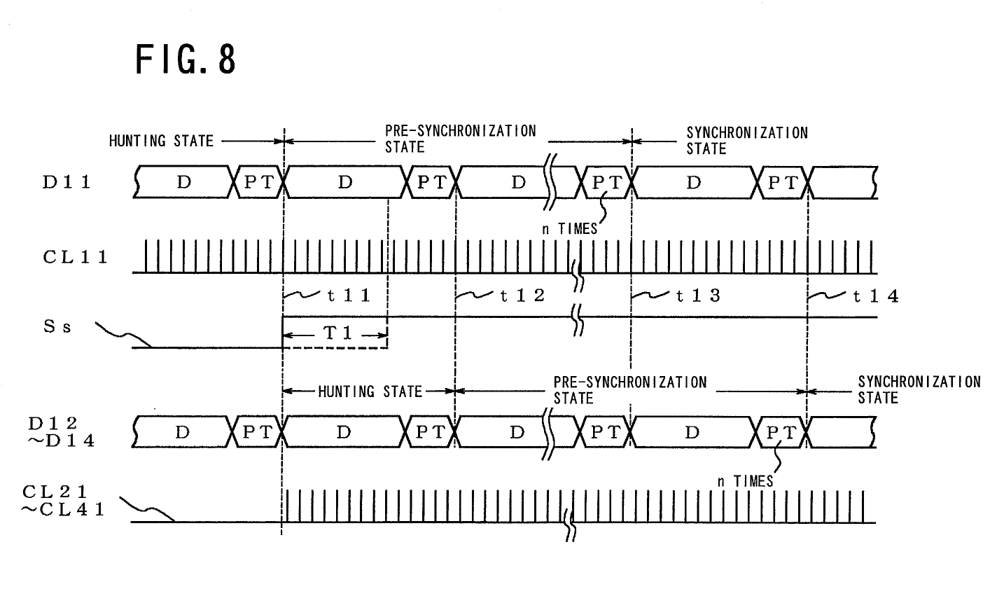

In particular, referring to FIG. 8, the master synchronization circuit 1 or 1A receives the main signal D11 and the operation clock CL11 to detect the synchronization pattern (PT) of the main signal D11, and changes from the hunting state to the pre-synchronization state at time t11 and sets the synchronization state signal Ss to the ‘H’ level. Thereafter, the master synchronization circuit 1 detects the synchronization pattern (PT) successively by n times while it is in the pre-synchronization state and then changes from the pre-synchronization state to the synchronization state at time t13.

Meanwhile, the slave synchronization circuits 2, 3 and 4 normally receive the supply of the main signals D12, D13 and D14 and receive the operation clocks CL21, CL31 and CL41 through the gate circuits 21, 31 and 41, respectively, at time t11 to start their operation.

Then, the slave synchronization circuits 2, 3 and 4 detect the synchronization pattern (PT) once at time t12 and changes from the hunting state to the pre-synchronization state. Thereafter, the slave synchronization circuits 2, 3 and 4 changes from the pre-synchronization state to the synchronization state at time t14 at which the synchronization pattern (PT) is detected successively by n times.

The operation described above with reference to FIG. 8 can be applied to the frame synchronism detection circuits described above with reference to FIGS. 1, 3, 5 and 6.

It has been described that, in the operation described above with reference to FIG. 8, the number of times of detection of the synchronization pattern after which the state change from the pre-synchronization state to the synchronization state occurs is n, any of the frame synchronism detection circuits described above with reference to FIGS. 1, 3, 5 and 6 may be configured otherwise such that the number is set to n for the master synchronization circuit 1 or 1A but to n−1 for the slave synchronization circuits 2, 3 and 4. With the configuration just described, the synchronism can be established at the same frame among the master synchronization circuit 1 and the slave synchronization circuits 2, 3 and 4.

Now, description is given particularly where n=2.

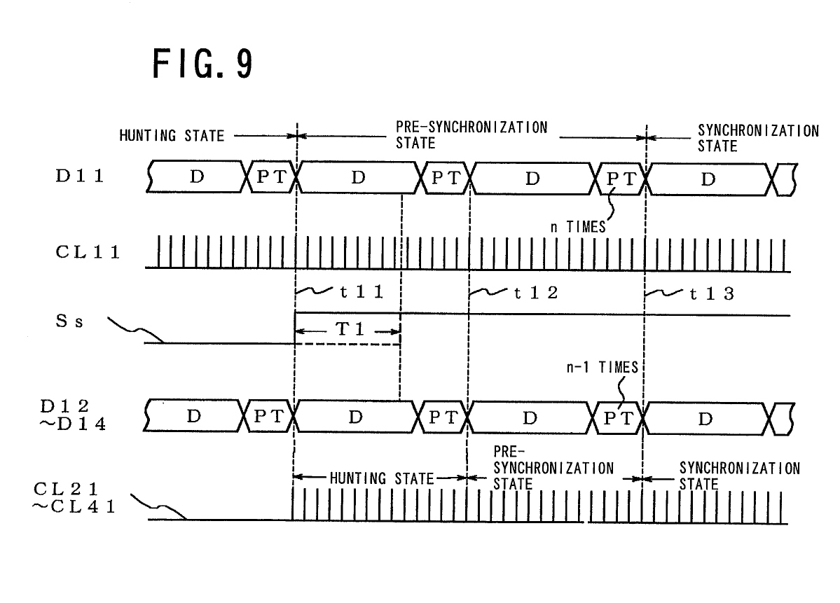

Referring to FIG. 9, the master synchronization circuit 1 or 1A detects the synchronization pattern (PT) of the main signal D11 and changes from the hunting state to the pre-synchronization state at time t11, whereupon it sets the synchronization state signal Ss to the ‘H’ level. Thereafter, the master synchronization circuit 1 detects the synchronization pattern (PT) successively twice (n times) while it is in the pre-synchronization state, and changes to the synchronization state at time t13.

Meanwhile, the slave synchronization circuits 2, 3 and 4 normally receive the supply of the main signals D12, D13 and D14 and receive the operation clocks CL21, CL31 and CL41 through the gate circuits 21, 31 and 41, respectively, at time t11 to start their operation.

Then, the slave synchronization circuits 2, 3 and 4 detect the synchronization pattern (PT) once at time t12 and change from the hunting state to the pre-synchronization state. Thereafter, at time t13 at which the slave synchronization circuits 2, 3 and 4 detect the synchronization pattern (PT) once (n−1 times), they change from the pre-synchronization state to the synchronization state. Consequently, the slave synchronization circuits 2, 3 and 4 establish the synchronism at the same frame as that of the master synchronization circuit 1.

Also the operation described above with reference to FIG. 9 can be applied to the frame synchronism detection circuits described above with reference to FIGS. 1, 3, 5 and 6.

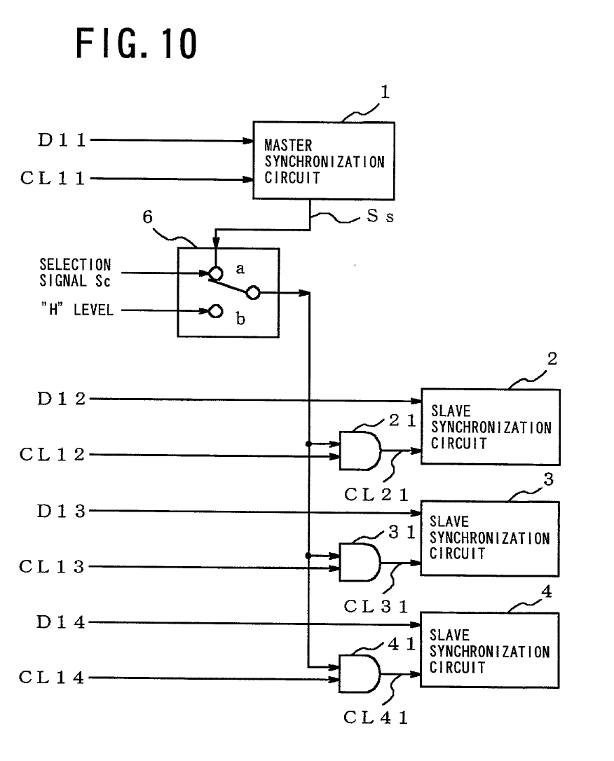

FIG. 10 shows a modification to the frame synchronism detection circuit of FIG. 1. Referring to FIG. 10, the modified frame synchronism detection circuit is different from the frame synchronization detection circuit of FIG. 1 in that it additionally includes a switch circuit 6 for selecting validity/invalidity of the synchronization state signal Ss outputted from the master synchronization circuit 1.

The synchronization state signal Ss outputted from the master synchronization circuit 1 is supplied to an input terminal a of the switch circuit 6 while a signal normally having the ‘H’ level is supplied to the other input terminal b of the switch circuit 6. The switch circuit 6 further receives a selection signal Sc from the outside and selects one of the input signals to the input terminals a and b thereof in accordance with the selection signal Sc. The selected signal is outputted to the gate circuits 21, 31 and 41.

If the switch circuit 6 selects the input terminal a, then the synchronization state signal Ss is rendered valid and the frame synchronism detection circuit operates in a similar manner as described hereinabove in connection with the frame synchronism detection circuit of FIG. 1. However, if the switch circuit 6 selects the input terminal b, then the synchronization state signal Ss is rendered invalid and the signal normally having the ‘H’ level is outputted from the switch circuit 6 to the gate circuits 21, 31 and 41. Accordingly, the slave synchronization circuits 2, 3 and 4 are permitted to operate independently of the master synchronization circuit 1 by controlling the switch circuit 6.

It is to be noted that the configuration of the frame synchronism detection circuit of FIG. 10 can be applied to all of the frame synchronism detection circuits described hereinabove with reference to FIGS. 1, 3, 5 and 6.

While preferred embodiments of the present invention have been described using specific terms, such description is for illustrative purposes only, and it is to be understood that changes and variations may be made without departing from the spirit or scope of the following claims.

What is claimed is:

1. A frame synchronism detection circuit, comprising:
a master synchronization circuit and a plurality of slave synchronization circuits for receiving individual main signals having frames including a synchronization pattern at substantially same timings and operation clocks for the main signals to establish synchronism; and
synchronization circuit controlling means for controlling said slave synchronization circuits to start operation to establish synchronism after said master synchronization circuit enters a synchronization state or a pre-synchronization state.

2. A frame synchronism detection circuit as claimed in claim 1, wherein said synchronization circuit controlling means controls the main signals or/and the operation clocks to be supplied to said slave synchronization circuits to cause said slave synchronization circuits to start the operation.

3. A frame synchronism detection circuit as claimed in claim 1, wherein said master synchronization circuit determines transition from a hunting state to the pre-synchronization state when the synchronization pattern is detected once, and then determines transition to the synchronization state when the synchronization pattern is detected successively by n times, n being an integer equal to or greater than 2.

4. A frame synchronism detection circuit as claimed in claim 3, wherein each of said slave synchronization circuits determines transition from the hunting state to the pre-synchronization state when the synchronization pattern is detected once after the operation thereof is started, and then determines transition to the synchronization state when the synchronization pattern is detected successively by n times.

5. A frame synchronism detection circuit as claimed in claim 3, wherein each of said slave synchronization circuits determines transition from the hunting state to the pre-synchronization state when the synchronization pattern is detected once after the operation thereof is started, and then determines transition to the synchronization state when the synchronization pattern is detected successively by n−1 times.

6. A frame synchronism detection circuit as claimed in claim 1, wherein said synchronization circuit controlling means delays starting of the operation of said slave synchronization circuits within a period of time until a next synchronization pattern is inputted to said master synchronization circuit after said master synchronization circuit enters the synchronization state or the pre-synchronization state.

7. A frame synchronism detection circuit as claimed in claim 1, wherein said synchronization circuit controlling means supplies only those portions of the main signals in the proximity of the synchronization pattern to said slave synchronization circuits.

8. A frame synchronism detection circuit as claimed in claim 1, wherein said synchronization circuit controlling means includes a switch circuit for selecting validity/invalidity of the signals to be outputted to said slave synchronization circuits.

9. A frame synchronism detection circuit as claimed in claim 1, wherein said master synchronization circuit receives one of the main signals and one of the operation clocks to detect the synchronization pattern and outputs a synchronization state signal when said master synchronization circuit establishes synchronism, said synchronization circuit controlling means including gate circuits for individually receiving the other operation clocks than the operation clock supplied to said master synchronization circuit and controlling supply of the received operation clocks to said slave synchronization circuits in response to the synchronization state signal, said slave synchronization circuits starting the operation based on the other main signals than the main signal supplied to said master synchronization circuit and the operation clocks individually supplied thereto through said gate circuits.

10. A frame synchronism detection circuit as claimed in claim 1, wherein said master synchronization circuit receives one of the main signals and one of the operation clocks to detect the synchronization pattern and outputs a synchronization state signal when said master synchronization circuit establishes synchronism, said synchronization circuit controlling means including gate circuits for individually receiving the other main signals than the main signal supplied to said master synchronization circuit and controlling supply of the received main signals to said slave synchronization circuits in response to the synchronization state signal, said slave synchronization circuits starting the operation based on the other operation clocks than the operation clock supplied to said master synchronization circuit and the main signals individually supplied thereto through said gate circuits.

11. A frame synchronism detection circuit as claimed in claim 1, wherein said master synchronization circuit receives one of the main signals and one of the operation clocks to detect the synchronization pattern and outputs a synchronization state signal when said master synchronization circuit establishes synchronism, said synchronization circuit controlling means including first gate circuits for individually receiving the other operation clocks than the operation clock supplied to said master synchronization circuit and controlling supply of the received operation clocks to said slave synchronization circuits in response to the synchronization state signal and second gate circuits for individually receiving the other main signals than the main signal supplied to said master synchronization circuit and controlling supply of the received main signals to said slave synchronization circuits in response to the synchronization state signal, said slave synchronization circuits starting the operation based on the operation clocks and the main signals individually supplied thereto through said first gate circuits and said second gate circuits, respectively.

12. A frame synchronism detection circuit as claimed in claim 1, wherein said master synchronization circuit receives one of the main signals and one of the operation clocks to detect the synchronization pattern and outputs a timing position signal representative of the proximity of the synchronization pattern after said master synchronization circuit establishes synchronism, said synchronization circuit controlling means including gate circuits for individually receiving the other main signals than the main signal supplied to said master synchronization circuit and controlling supply of the received main signals to said slave synchronization circuits in response to the timing position signal, said slave synchronization circuits starting the operation based on the other operation clocks than the operation clock supplied to said master synchronization circuit and the main signals only in the proximity of the synchronization pattern individually supplied thereto through said gate circuits.
